(19) United States
(12) Patent Application Publication
(10) Pub. No.: US 2026/0176127 A1
(43) Pub. Date: Jun. 25, 2026

(54) System And Method For Generating An Audio Signal

(71) Applicant: SONICEDGE LTD., Shoham (IL)

(72) Inventor: Mordehai Margalit, Zichron Yaaqov (IL)

(21) Appl. No.: 19/540,831

(22) Filed: Feb. 16, 2026

Related U.S. Application Data
(63) Continuation-in-part of application No. 18/542,851, filed on Dec. 18, 2023, now Pat. No. 12,598,414.
(60) Provisional application No. 63/433,507, filed on Dec. 19, 2022.
(60) Provisional application No. 63/433,507, filed on Dec. 19, 2022.

(51) Int. Cl. B81B 3/00; H04R 19/00; H10W 20/00

(52) U.S. Cl. CPC B81B 3/0021; H04R 19/005; H10W 20/072

(57) ABSTRACT

A MEMS transducer having a hierarchical anchoring architecture is disclosed. The transducer comprises a substrate, a base dielectric layer on the substrate, and a middle membrane layer anchored to the substrate via primary support posts. The middle membrane layer constitutes the sole structural interface between the transducer and the substrate. A top membrane layer and a bottom membrane layer are mechanically suspended from the middle membrane layer via membrane support posts rather than being independently anchored to the substrate. The middle membrane layer includes conductive portions and non-conductive portions at support post contact areas, providing electrical isolation between the membrane layers. Additional dielectric structures protect the non-conductive portions from sacrificial etch. The architecture simplifies fabrication, reduces the number of substrate anchor points, and enables a compact, mechanically robust MEMS speaker device.

### CROSS-REFERENCE TO RELATED APPLICATIONS

This application is a continuation-in-part of U.S. patent application Ser. No. 18/542,851 filed on Dec. 18, 2023.

### BACKGROUND OF THE DISCLOSURE

U.S. Pat. No. 8,861,752 describes a picospeaker which is a novel sound generating device and a method for sound generation. The picospeaker creates an audio signal by generating an ultrasound acoustic beam which is then actively modulated. The resulting modulated ultrasound signal has a lower acoustic frequency sideband which corresponds to the frequency difference between the frequency of the ultrasound acoustic beam and the modulation frequency. US20160360320 and US20160360321 describe MEMS architectures for realizing the picospeaker. US20160277838 describes one method of implementation of the picospeaker using MEMS processing. US20160277845 describes an alternative method of implementation of the picospeaker using MEMS processing.

State of art approaches to realizing the picospeaker are complex and require many processing steps. Hence it is desirable to provide an architecture and method of implementation which reduces the complexity and number of processing steps.

### SUMMARY

In accordance with an embodiment, a MEMS transducer includes a substrate; a base dielectric layer disposed on a surface of the substrate; a middle membrane layer anchored to the substrate via at least two primary support posts extending through at least one dielectric layer to the base dielectric layer, the middle membrane layer constituting the sole structural interface for supporting membrane layers between the MEMS transducer and the substrate; and at least one of a top membrane layer and a bottom membrane layer mechanically suspended from the middle membrane layer via at least one membrane support post. The middle membrane layer comprises one or more conductive portions and one or more non-conductive portions, the non-conductive portions positioned at contact areas of the membrane support posts with the middle membrane layer.

### Glossary

“acoustic signal”—as used in the current disclosure means a mechanical wave traversing either a gas, liquid or solid medium with any frequency or spectrum portion between 10 Hz and 10,000,000 Hz.

“audio” or “audio spectrum” or “audio signal”—as used in the current disclosure means an acoustic signal or portion of an acoustic signal with a frequency or spectrum portion between 10 Hz and 20,000 Hz.

“speaker” or “pico speaker” or “micro speaker” or “nano speaker”—as used in the current disclosure means a device configured to generate an acoustic signal with at least a portion of the signal in the audio spectrum.

“membrane”—as used in the current disclosure means a flexible structure constrained by at least two points.

“blind”—as used in the current disclosure means a structure with at least one acoustic port through which an acoustic wave traverses with low loss.

“shutter”—as used in the current disclosure means a structure configured to move in reference to the blind and increase the acoustic loss of the acoustic port or ports.

“acoustic medium”—as used in the current disclosure means any of but not limited to; a bounded region in which a material is contained in an enclosed acoustic cavity; an unbounded region where in which a material is characterized by a speed of sound and unbounded in at least one dimension. Examples of acoustic medium include but are not limited to; air; water; ear canal; closed volume around ear; air in free space; air in tube or other acoustic channel.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are therefore not to be considered limiting of its scope, the disclosure will be described with additional specificity and detail through use of the accompanying drawings.

FIG. 1A is an example of a side view of a state of art architecture for a MEMs picospeaker cell;

FIG. 1B is an example of a top view of a matrix arrangement of a plurality of cells adapted from US20160277845;

FIG. 2A is an example of a top view of picospeaker with a simplified process flow comprising multiple, electrically interconnected picospeaker cells;

FIG. 2B and FIG. 2C are an example of membrane and shutter layers respectively of a picospeaker cell from FIG. 2A;

FIG. 2D is an example of a blind layer of a picospeaker cell from FIG. 2A;

FIG. 3A is an example of a top view of cell and cutout along line of a picospeaker cell during fabrication;

FIG. 3B depicts resulting holes for pillar support in second dielectric layer;

FIG. 3C shows a third dielectric layer deposited above first conductive layer;

FIG. 3D shows resulting holes for pillar support in third dielectric layer;

FIG. 3E shows a fourth dielectric layer deposited above second conductive layer;

FIG. 3F depicts resulting holes for pillar support in fourth dielectric layer;

FIG. 3G depicts a fifth dielectric layer deposited on third conductive layer;

FIG. 4 depicts a cutout along the center of a picospeaker cell of FIGS. 3A-3G.

FIG. 5 is an example of a cross-sectional side view of a MEMS transducer having a hierarchical anchoring architecture in accordance with an embodiment of the present disclosure.

FIG. 6A is an example of a detailed cross-sectional view of an isolation island in accordance with an embodiment of the present disclosure.

FIG. 6B is an alternative example of a detailed cross-sectional view of an isolation island, illustrating an alternative process flow for the middle membrane layer.

FIG. 7A is an example of a top view of a membrane, spoke, and post arrangement in accordance with an embodiment of the present disclosure.

FIG. 7B is an example of a top view of the speaker device using a hierarchical anchoring architecture in accordance with an embodiment of the present disclosure.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other examples may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure. This disclosure is drawn, inter alia, to methods, apparatus, computer programs, and systems of generating an audio signal.

In an embodiment, the speaker device includes a first conductive layer with a plurality of center structures and springs; a second conductive layer with a plurality of perforations; and electrical isolation rings; a third conductive layer with a plurality of center structures and springs; and a dielectric layer. The first, second and third conductive layers are in physical contact with the dielectric layer and are electrically isolated from each other.

In some examples, a speaker device is described that includes a membrane and a shutter. The membrane is configured to oscillate along a first directional path and at a combination of frequencies with at least one frequency effective to generate an ultrasonic acoustic signal. A shutter and blind are positioned proximate to the membrane. In one non limiting example the membrane, the blind, and the shutter may be positioned in a substantially parallel orientation with respect to each other. In other examples the membrane, the blind, and the shutter may be positioned in the same plane and the acoustic signal is transmitted along acoustic channels leading from the membrane to the shutter. In a further example the modulator and or shutter are composed of more than one section.

In some embodiments, the membrane is driven by an electric signal that oscillates at a frequency Ω and hence moves at b Cos(2π*Ωt), where b is the amplitude of the membrane movement, and t is time. The electric signal is further modulated by a portion that is derived from an audio signal a(t). The acoustic signal is characterized as:

$$s ( t ) = b a ( t ) Cos ( 2 π * Ω t ) \qquad ( 1 )$$

Applying a Fourier transform to Equation (1) results in a frequency domain representation

$$S ( f ) = b / 2 * [ A ( f - Ω ) + A ( f + Ω ) ] \qquad ( 2 )$$

Where A(f) is the spectrum of the audio signal. Equation (2) describes a signal with an upper and lower side band around a carrier frequency of 0. Applying to the acoustic signal of Equation (1) an acoustic modulator operating at frequency Ω results in

$$S ( t ) = b a ( t ) Cos ( 2 π * Ω t ) ( I + m Cos ( 2 π * Ω t ) ) \qquad ( 3 )$$

Where l is the loss of the modulator and m is the modulation function and due to energy conservation l+m<1. In the frequency domain

$${S}^{′} ( f ) = b / 4 * [ m A ( f ) + m A ( f + 2 Ω ) + A ( f - Ω ) + A ( f + Ω ) ] \qquad ( 4 )$$

Where b/4*m A(f) is an audio signal. The remaining terms are ultrasound signals where m A(f+2Ω) is at twice the modulation frequency and A(f−Ω)+A(f+Ω) is the original unmodulated signal. Additional acoustic signals may be present due to any but not limited to the following; ultrasound signal from the shutter movement; intermodulation signals due to nonlinearities of the acoustic medium; intermodulation signals due to other sources of nonlinearities including electronic and mechanical.

In a further example the audio signal is enhanced by acoustic radiation pressure of the ultrasound signal. This is a new approach to audio generation where the audio system generates an ultrasound signal. The ultrasound signal exerts a radiation force on surfaces on which it impinges including the Tympanic membrane (ear drum). By modulating the ultrasound signal the radiation force magnitude can be changed, thereby effecting mechanical movement of the Tympanic membrane which is registered as sound by the ear (and brain). The radiation pressure of an acoustic signal is well documented and given as

$$P = α E = α \frac{{p}^{2}}{ρ {c}^{2}} \qquad ( 5 )$$

Where P is the radiation pressure, and where E, p, ρ, and c are energy density of the sound beam near the surface, acoustic pressure, density of the sound medium, and the sound velocity, respectively. α is a constant related to the reflection property of the surface. If all the acoustic energy is absorbed on the surface, a is equal to 1, while for the surface that reflects all the sound energy, α is 2. The sound power E carried by the beam is E=W/c where W is the power density of the transducer. In one example to effect an audio sensation at the ear drum an ultrasound signal is modulated with an audio signal. The audio signal causes changes in the acoustic radiation force which are registered as an audio signal by the ear. In one non limiting example the audio is AM modulated on the ultrasound carrier

$$S ( t ) = Cos ( 2 π * Ω t ) ( I + m a ( t ) ) \qquad ( 6 )$$

E is proportional to m a(t) and the changes in the radiation force P are proportional to m a(t) resulting in movement of the eardrum which is proportional to m a(t). Hence an ultrasound speaker can generate sound using any or both methods described above. In one example the methods are used intermittently, in another example the methods are used concurrently, in another example only modulation or only radiation force are used.

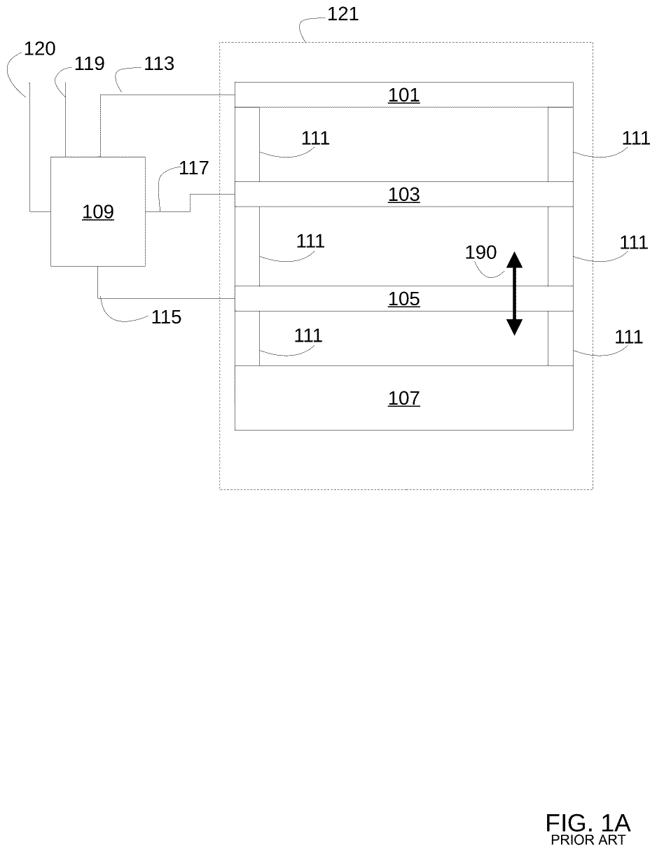

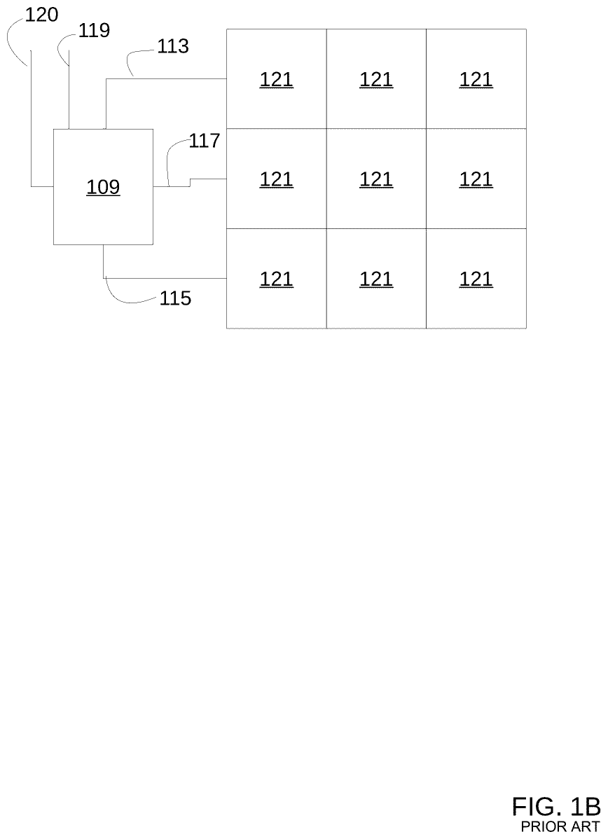

FIG. 1A is an example of a side view of a state of art architecture for a MEMs picospeaker cell (121). The picospeaker cell is composed of at least three layers. Membrane (105), which generates the acoustic signal described in Equation (1) by moving in the direction of arrows (190). Blind (103) and shutter (101) move relative to each other and modulate the acoustic signal as described in Equation (3). In one example driving device (109) provides one voltage signal to membrane (105) and a second voltage signal to shutter (101) and the voltage to blind (103) is set at zero or ground. The first and second voltage signals provide the driving force to generate the acoustic sound of Equation (1) and the modulation function of Equation (3) respectively. In an additional example a fourth layer; handle (107) is included. The driving device (109) is electrically connected to a digital audio source via line (119), low voltage source via line (120), membrane layer (105) via line (115), blind layer (103) via line (117) and shutter layer (101) via line (113). The picospeaker device is composed of multiple picospeaker cells (121). FIG. 1B is an example of a top view of a matrix arrangement of a plurality of cells (121) adapted from US20160277845 the content of which is hereby incorporated into this specification by reference. The cells (121) are electrically connected in parallel so that a first drive voltage is applied to all membranes (FIG. 1A 105) in the connected cells (121) and a second drive voltage is applied to all shutters (FIG. 1A 101) in the connected cells (121).

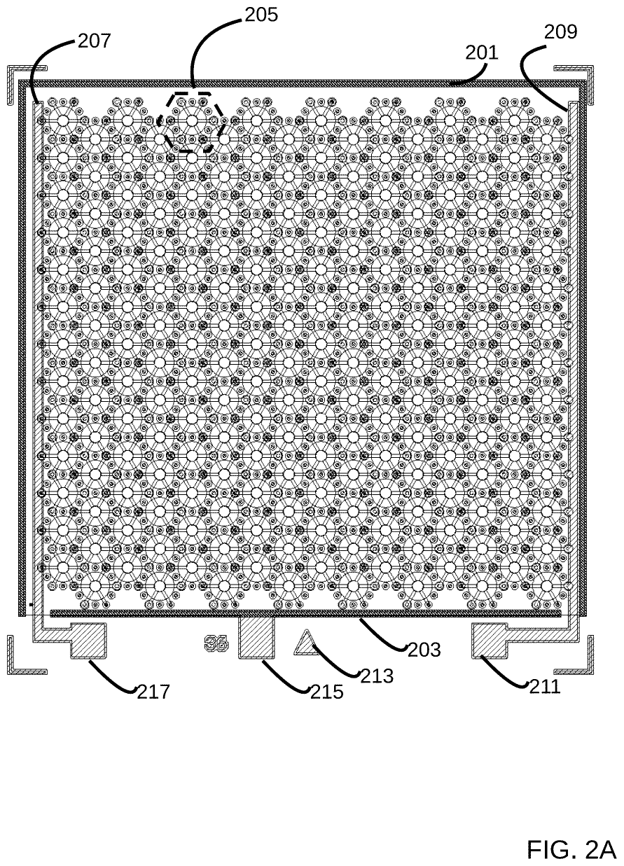

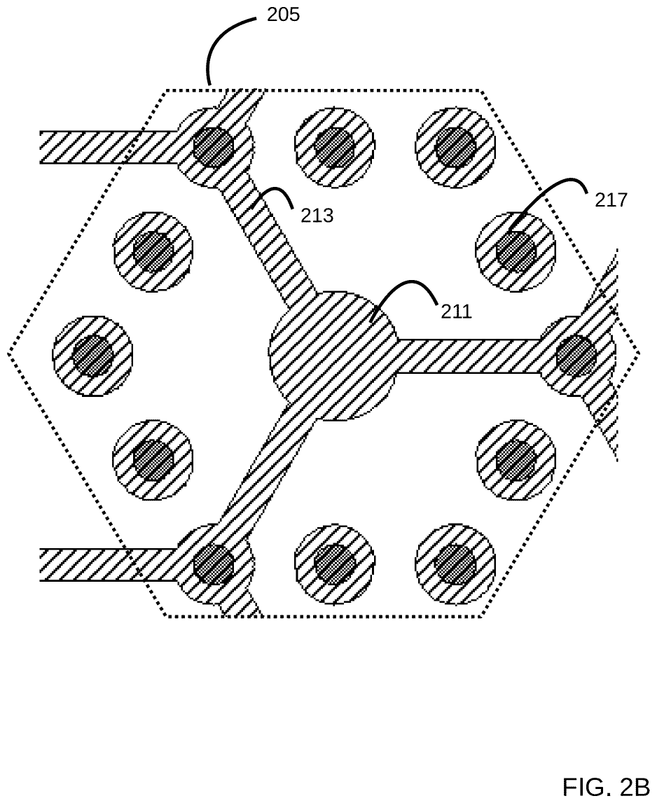

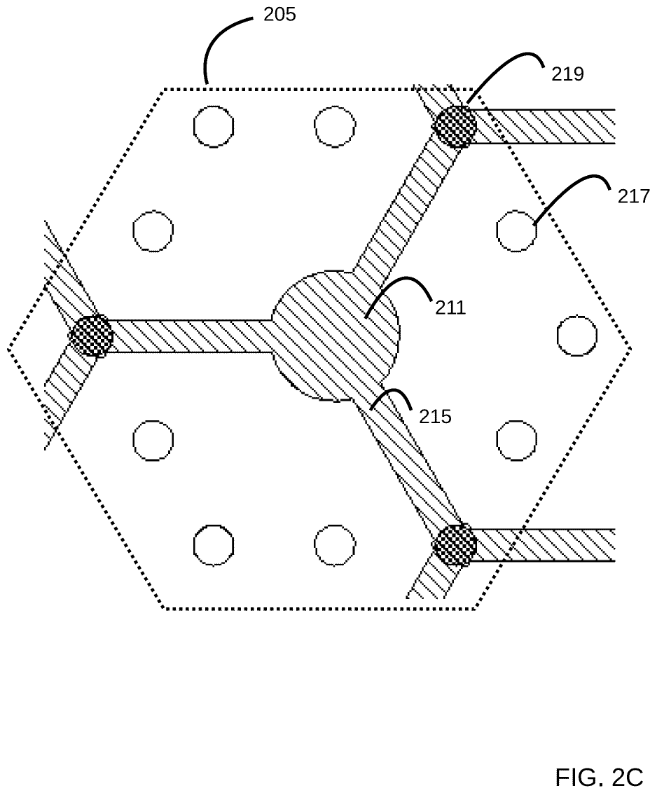

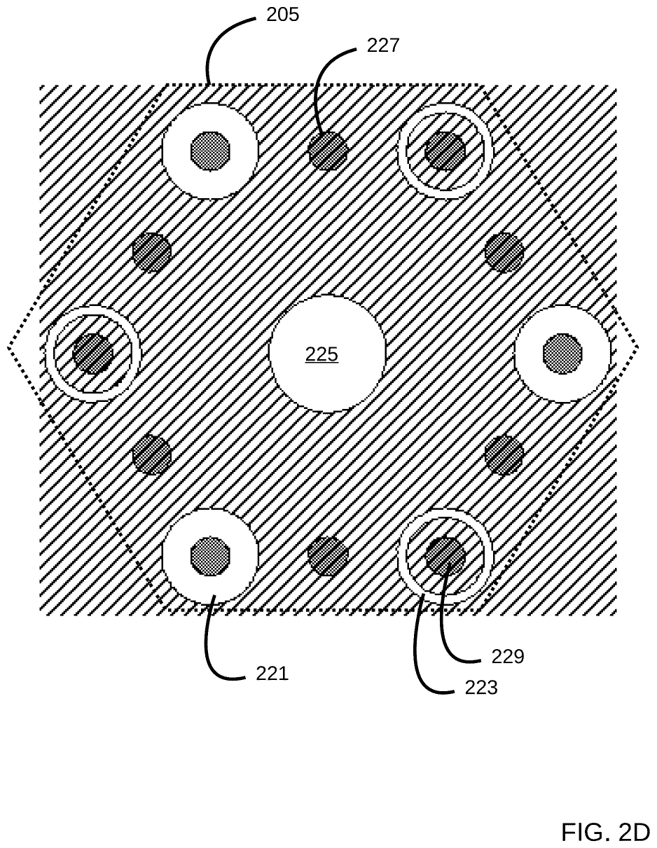

FIG. 2A is an example of a top view of picospeaker with a simplified process flow comprising multiple, electrically interconnected picospeaker cells (205) which will be described in FIG. 2B. Each of the three layers described in FIG. 1, membrane, shutter and blind, is electrically connected to at least one electrical pad (211, 215, 217). A voltage applied on one pad will be the applied voltage to the membrane layer, a voltage applied to a second pad will be the voltage applied to the shutter layer and a zero voltage or ground applied to a third pad will be the voltage applied to the blind. In alternative examples, the voltages and ground may be applied to any combination of layers. In a further example; pad (211) is in electrical contact with bus (209) which is connected to any of the membrane, blind or shutter layers; pad (215) is in electrical contact with bus (203) which is connected to any of the membrane, blind or shutter layers; and pad (217) is in electrical contact with bus (207) which is connected to any of the membrane, blind or shutter layers. In a further example additional pads and/or busses may provide electrical connection to any of the membrane; shutter or blind layers. In a further example, any of the membrane; blind and or shutter layers are composed of one or more electrically isolated portions so that a pad would only connect to a portion of said layer. This would enable operating only a partial number of picospeaker cells. In a further example the picospeaker includes a frame (201). The frame connects the blind layer to the substrate and prevents leakage of air from below the blind to above the blind from the sides of the blind. Hence a frame provides an air tight closure between blind and substrate. Electrical bus (203) is an example of a pad connected to a frame and providing both air tight connection as well as electrical connection to blind layer. In a further example a picospeaker includes visible markings (213). Examples of markings include but are not limited to; die alignment or position mark; die dicing marks; die number mark; logos or other markings; any combination of these marks. In a further example a frame (201, 203) covers at least any of but not limited to more than 50%; more than 70%; more than 90%; more than 95% of the perimeter of the blind membrane layer.

FIG. 2B and FIG. 2C are an example of membrane and shutter layers respectively of a picospeaker cell (205) from FIG. 2A. Membrane and shutter layer are comprised as central structures (211) with springs (213, 215). In one example membrane and shutter structures are similar in size and form. In an alternative example membrane and shutter structures differ in size or form, and the structure with the lower mechanical resonance frequency is designated as the shutter. In a further example the structure has any off but not limited to 1; 2; 3; 4; 5; 6; 7; 8 spring structures. A central structure is any off but not limited to rectangle; triangle; square; hectogon; hexagon; heptagon; octagon; circle; or any radially symmetric shape. The central structure at least partially overlaps a perforation in the blind layer. The overlap defines the modulation factor m of equation (2). In a further example the overlap extends over at least 50% of the perimeter of the perforation and has a width of any off but not limited to 1-3 micron; 2-4 micron; 3-5 micron; 4-6 micron; 5-10 micron; 10 to 15 micron. Examples of springs (213, 215) include but are not limited to straight beams; S shaped springs; U shaped springs; zig zag shaped springs or any shape connecting any anchor (e.g. 217, 219) to the central structure (211). The spring and central structure comprise a mechanical structure with a mechanical resonant frequency of any of but not limited to; less than 200 KHz; 200-300 KHz; 300-400 KHz; above 400 KHz; above 600 KHz; above 1 MHz. Anchor (217,219) structures provide mechanical support and scaffolding for a membrane; blind or shutter layer which maintains electrical isolation between the layers. Anchor structures (217) extend over all anchors for bottom layer; and over a smaller portion of anchor structures in consecutive layers. As a further example, in FIG. 2C a top layer with only three anchors (219) is demonstrated. FIG. 2D is an example of a blind layer of a picospeaker cell (205) from FIG. 2A.

In one example a blind layer is situated between shutter and membrane layers. Blind layer includes at least one or more perforation (225); isolation ring (223); and anchor (227) for blind layer. Isolation ring (223) electrically isolates blind layer from anchor (229) of layer located above blind layer. Isolation ring (223) prevents electrical connection between blind layer and layer located above it while enabling mechanical support of layer above blind layer and electrical connection from layer above blind layer to respective electrical pad or pads. In a further example, blind layer includes an additional capacitance reduction perforation (221) located above anchor of layer below blind layer. Capacitance reduction perforation (221) area is any of but not limited to smaller than 5 micron; square; 10 micron square; 20 micron square; 40 micron square; 60 micron square.

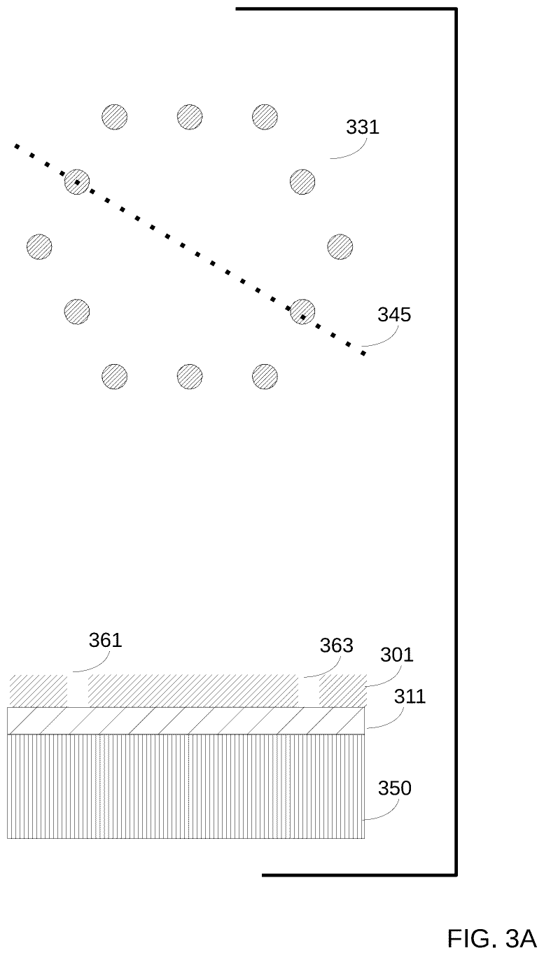

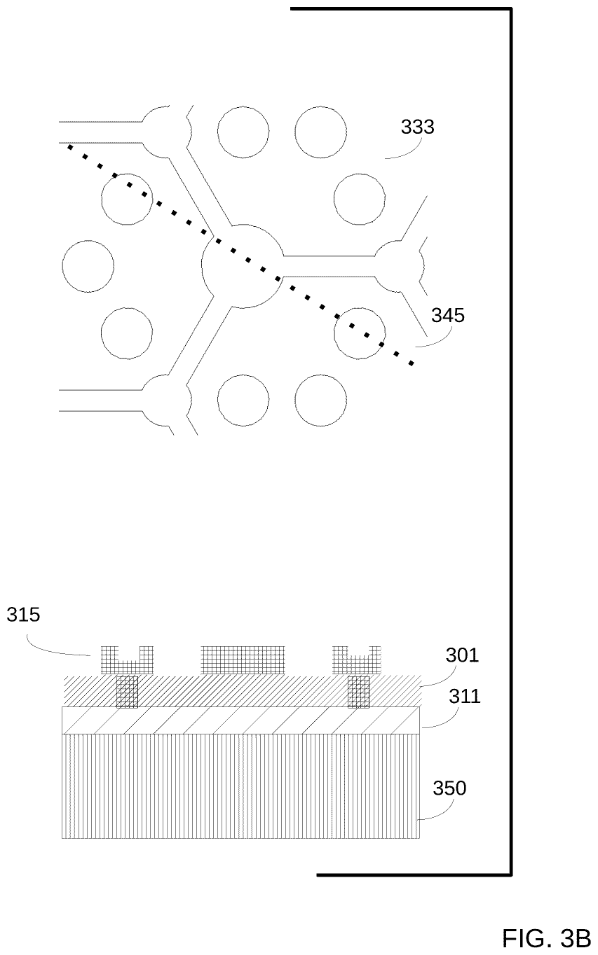

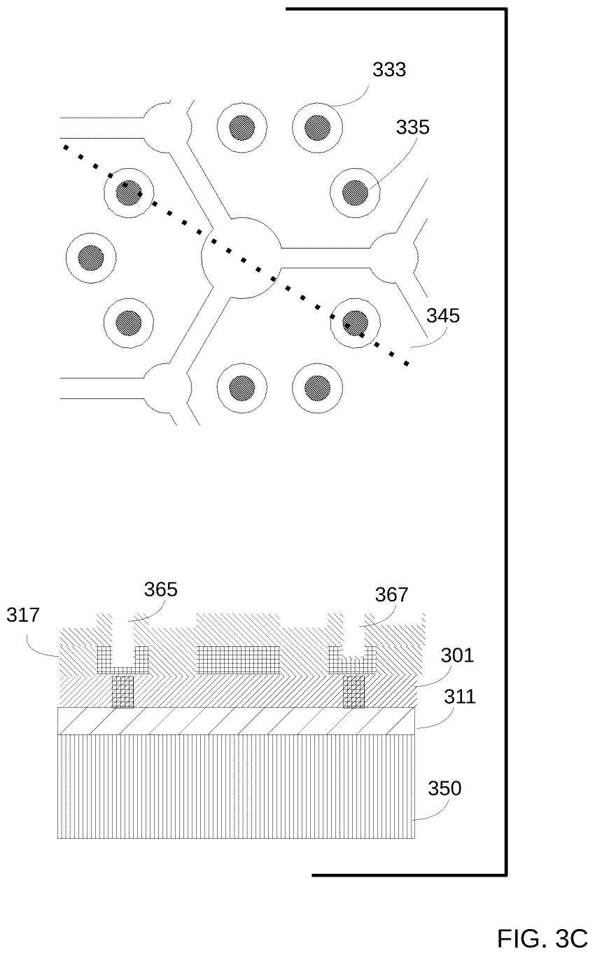

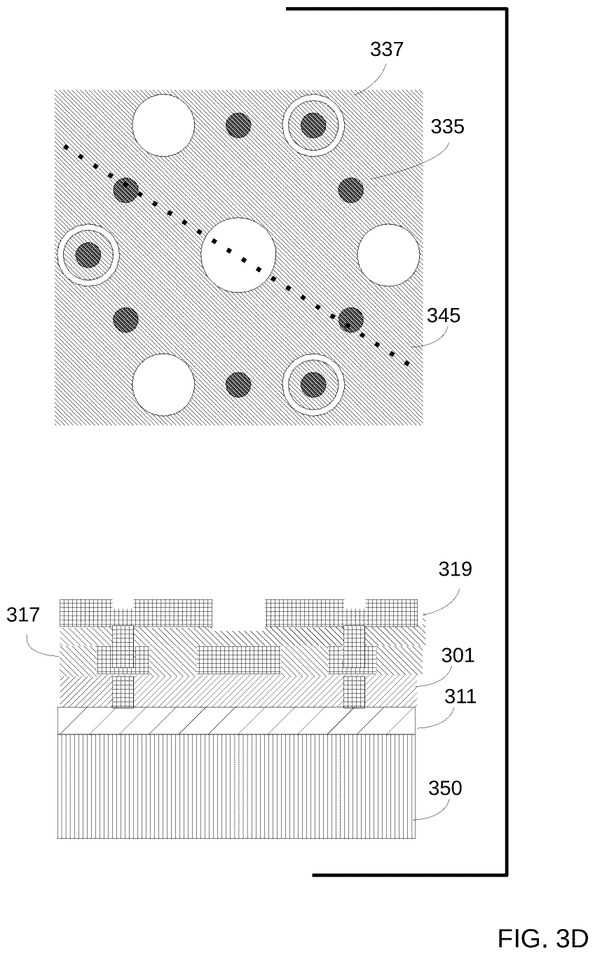

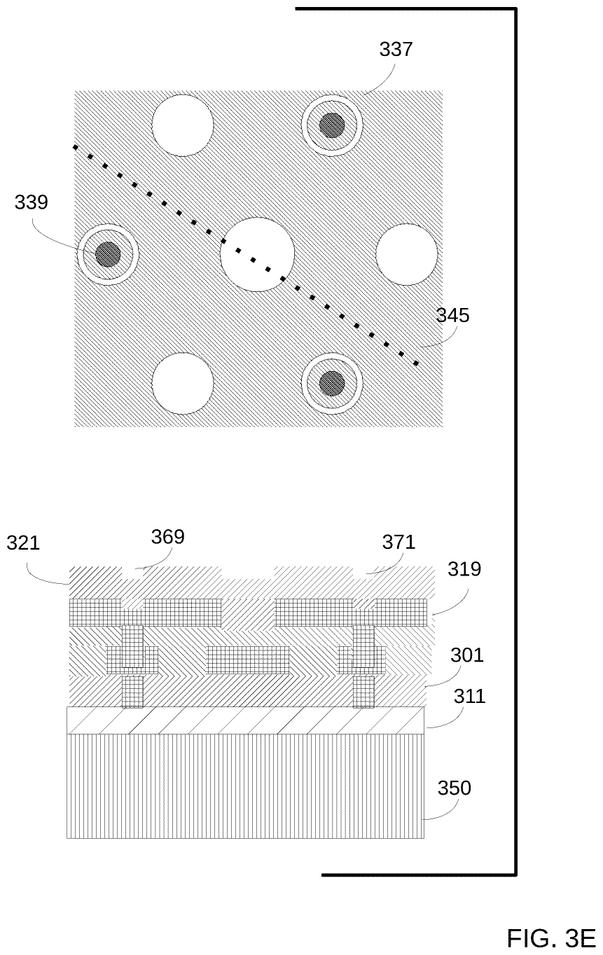

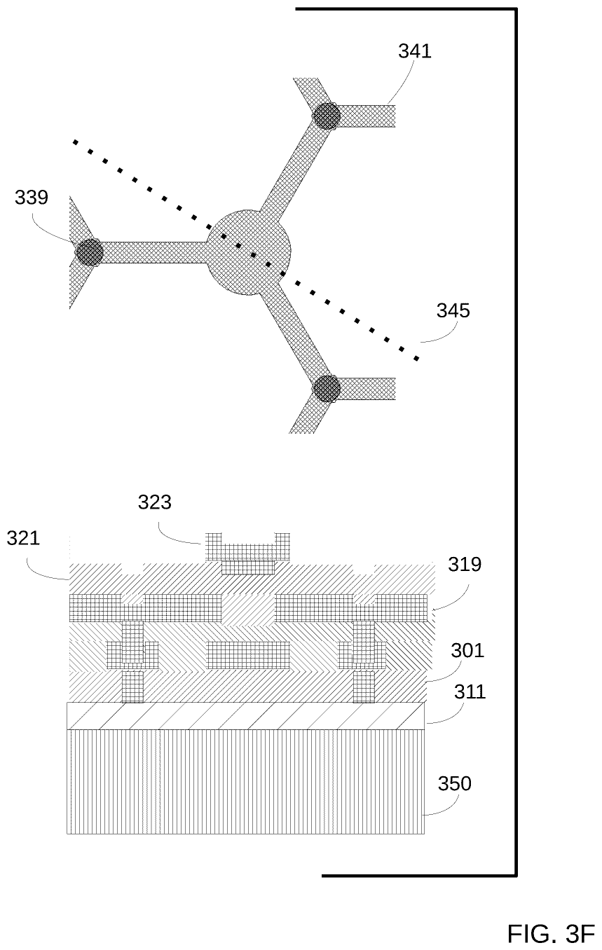

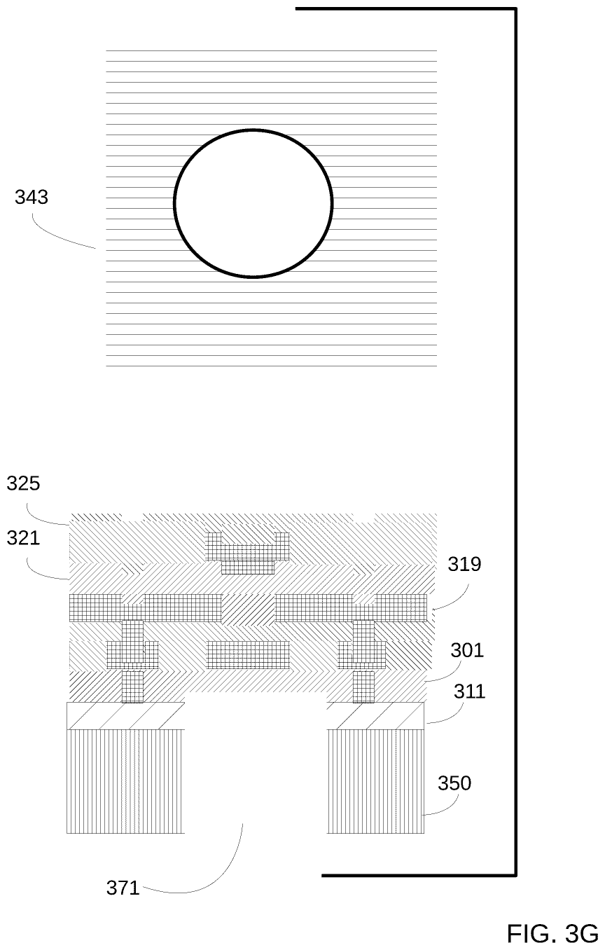

FIGS. 3A-3G are an example of a simplified process flow for fabrication of a picospeaker. FIG. 3A is an example of a top view of cell (331) and cutout along line (345) of a picospeaker cell during fabrication after conducting the following processing steps; a silicon wafer (350) is coated with a first dielectric layer (311) and a second dielectric layer (301). A first dielectric layer (311) is comprised of dielectric materials with an etch selectivity in respect to second dielectric layer (301). Examples of materials for a first dielectric layer include but are not limited to SiN; SiRN; TIF; TaF; AlOx; AlN; TiO; TaO; SiO2; thermal SiO2; or combinations of these materials. In a further example a first dielectric layer is termed base dielectric and is characterized by a resistance to etch by HF and or VHF. A second dielectric (301) is a member of the dielectric stack comprising the sacrificial material or layers and they will be removed at the final stage of the process by a sacrificial etch. Examples of sacrificial etch include but are not limited to HF; VHF; Plasma Ashing; XeFe. Second dielectric layer (301) is patterned as shown in top view. Patterning is conducted by depositing a photo resist; exposing a mask pattern; developing said photoresist to exhibit said mask pattern; etching dielectric layer using the developed photoresist to isolate areas from etching. Examples of etching include but are not limited to wet etching including HF; VHF; dry etching including mechanical and chemical plasma etching; mechanical ion etching. The mask pattern is composed of holes, where each hole will provide the defining structure for support pillars. Support pillars can have any shape including but not limited to round; ellipse; rectangle; or multi-faceted shape. Area of support pillar is any of but not limited to; smaller than 10 micron square; smaller than 20 micron square; smaller than 50 micron square; smaller than 100 micron square. FIG. 3B depicts resulting holes for pillar support (FIG. 3A, 361, 363) will be filled with a first conducting layer (315) deposited above second dielectric layer (301). First conducting layer is patterned similarly to previous description with a deposited photoresist; exposure with mask; developing of photoresist; and etching of first conducting layer with pattern (333) creating both support structures; central structure and springs (FIG. 2B). In a further example photoresist includes a hard photo resist comprised of an intermediate non organic material which is first patterned using developed photoresist and then provides etch resistant layer for defining etch pattern. FIG. 3C describes a third dielectric layer (317) deposited above first conductive layer (315). In one example third dielectric layer is comprised of same material as second dielectric material (301) and further comprises part of sacrificial material stack. Third dielectric layer (317) is patterned similarly to previous description with a deposited photoresist; exposure with mask; developing of photoresist; and etching of third dielectric layer with pattern (335) defining holes for support structures. FIG. 3D depicts resulting holes for pillar support (FIG. 3C, 365, 367) will be filled with a second conductive layer (319) deposited above third dielectric layer (317). Second conductive layer (319) is patterned similarly to previous description with a deposited photoresist; exposure with mask; developing of photoresist; and etching of first conducting layer with pattern (333) creating both perforated structures as shown in (FIG. 2D).

In a further example the photoresist includes a hard photo resist comprised of an intermediate nonorganic material which is first patterned using developed photoresist and then provides etch resistant layer for defining etch pattern. FIG. 3E describes a fourth dielectric layer (321) deposited above second conductive layer (319). In one example fourth dielectric layer (321) is comprised of same material as second dielectric material (301) and further comprises part of sacrificial material stack. Fourth dielectric layer (321) is patterned similarly to previous description with a deposited photoresist; exposure with mask; developing of photoresist; and etching of third dielectric layer with pattern (337) defining holes 339 for support structures. FIG. 3F depicts resulting holes for pillar support (FIG. 3E 369, 371) will be filled with a third conductive layer (323) deposited above fourth dielectric layer (321). Third conductive layer (323) is patterned similarly to previous description with a deposited photoresist; exposure with mask; developing of photoresist; and etching of first conducting layer with pattern (341) creating both center structure and spring as shown in (FIG. 2C). In a further example photoresist includes a hard photo resist comprised of an intermediate non organic material which is first patterned using developed photoresist and then provides etch resistant layer for defining etch pattern. FIG. 3G depicts a fifth dielectric layer (325) deposited on third conductive layer (FIG. 3E 323). In a further example fifth dielectric layer (325) is comprised of the same dielectric material as second dielectric material (301) and comprises part of the sacrificial material stack. Silicon wafer (350) is patterned according to back side etch mask pattern (343). Silicon wafer etch is either DRIE etch or wet etch. Etch masks include photoresist or hard mask as described previously.

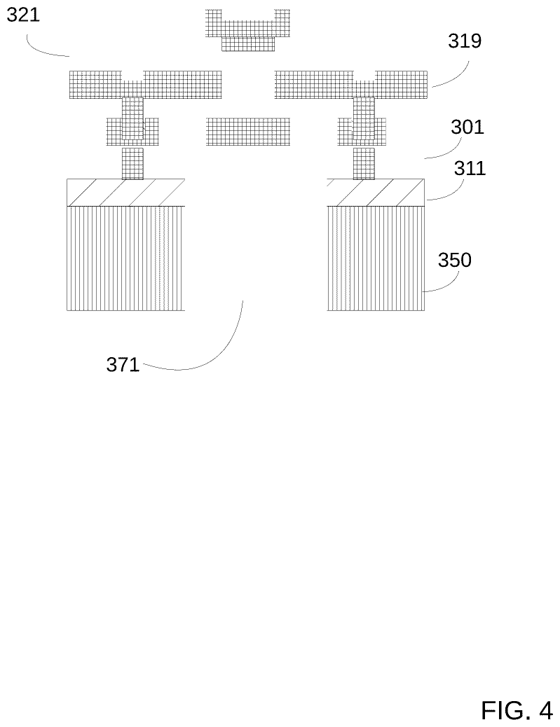

FIG. 4 describes a cutout along the center of a picospeaker cell as described in FIGS. 3A-3G, after removing the sacrificial layer using a sacrificial layer etch. Examples of etch include and are not limited to HF; VHF; Plasma Ashing; XeFe. Examples of sacrificial layers include but are not limited to SiO2; SiOx; aSi; polymers. Examples of conductive layer materials include but are not limited to; doped Polysilicon; metals including Al; AlCu; AlSiCu; Nickel. Conductive materials can include a bottom and or top layer of dielectric material including SiN; SiRN; TIF; TIO; AlOx and combinations of these. In a further example, prior to a backside etch, a pad reveal pattern is defined to provide a mask for etching the dielectric layers two to five to expose pads (FIG. 2A 211, 215, 217). A pad metal is deposited on exposed pads. In one example pad metal definition is done using either lift off process (deposition of photo resist; exposure of mask; developing of photo resist with opening for pads; deposition of metal; and removal of photoresist leaving metal just on pads). In an alternative example metal pads are defined by metal layer deposition; photoresist deposition exposure; developing and then etching metal layer according to developed photo resist. Example of metal pads include but are not limited to Al; AlCu; AlSiCu; Gold; Ti; Cr; Nickel or combinations of these materials. In a further example thickness ranges (all numbers are in microns) for the layers are shown in the table below:

| | Min | Max | Typical |
|---|---|---|---|
| Layer | thickness | thickness | thickness |
| First dielectric layer | 0.1 | 2.0 | 0.2 |
| Second dielectric layer | 0.1 | 6.0 | 1.0 |
| First conductive layer | 0.2 | 5.0 | 1.5 |
| Third dielectric layer | 1.0 | 6.0 | 2.5 |
| Second conductive layer | 0.2 | 10.0 | 2.0 |
| Fourth dielectric layer | 1.0 | 6.0 | 2.5 |
| Third conductive layer | 0.2 | 5.0 | 1.5 |
| Fifth dielectric layer | 0.1 | 5.0 | 1.0 |

To sum we present a speaker device comprised of a first conductive layers with a plurality of center structures and springs; a second conductive layer with a plurality of perforations; and electrical isolation rings; a third conductive layer with a plurality of center structures and springs; a dielectric layer; wherein first, second and third conductive layers are in physical contact with dielectric layer and are electrically isolated from each other. In a further example the second conductive layer is physically connected to dielectric layer at its perimeter with at least 70 percent of its perimeter and restricts airflow from bottom side second conductive layer to top side of second conductive layer to substantially a set of perforations in the second conductive layer. In a further example second conductive layer is physically connected to dielectric layer at its perimeter with any of but not limited to at least 60 percent; at least 80 percent; at least 90 percent; of its perimeter and restricts airflow from bottom side second conductive layer to top side of second conductive layer to substantially a set of perforations in the second conductive layer. In a further example the conductive layers are any of but not limited to polysilicon; doped polysilicon; Al; AlCu; AlSiCu; Ni. In further example the stress in the conductive layer is tensile. In a further example the stress in the conductive layer is any of but not limited to; less than 30 Mpa; less than 50 Mpa; Less than 100 Mpa; Less than 300 Mpa. In a further example the conductance of the conductive layer is any of but not limited to less than 10 Ohm per square; less than 50 Ohm per square; less than 500 Ohm per square; less than 1 KOhm per square. In a further example the dielectric layer material is any of SiN; SiRN; TiN; TaO; TaN; AlOx; SiO2.

There is little distinction left between hardware and software implementations of aspects of systems; the use of hardware or software is generally (but not always, in that in certain contexts the choice between hardware and software can become significant) a design choice representing cost versus efficiency tradeoffs. There are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

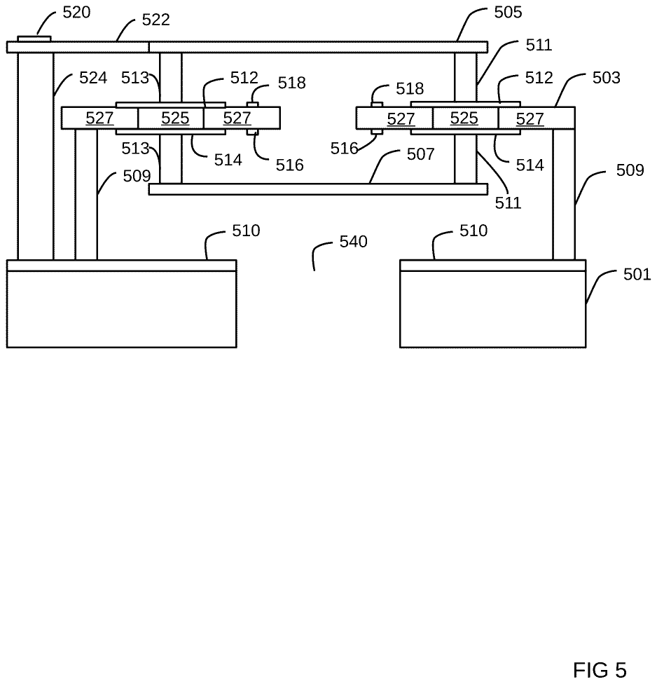

Reference is now made to FIGS. 5 through 7B, which illustrate embodiments of a MEMS transducer having a hierarchical or cascaded anchoring architecture. The embodiments described herein may be implemented in conjunction with, or as an alternative to, any of the structures, materials, and fabrication methods described above. As described above, the MEMS transducer employs a substrate-centric anchoring scheme in which each functional layer—for example, the membrane layer, the blind layer, and the shutter layer—is independently coupled to the substrate via respective support pillars extending through the dielectric stack (see, e.g., FIGS. 3A-4). In the hierarchical anchoring architecture described below, a single layer-referred to as the middle membrane layer—serves as the primary structural backbone for the entire device. The remaining layers are mechanically suspended from the middle membrane layer rather than being independently anchored to the substrate.

FIG. 5 is an example of a cross-sectional side view of a MEMS transducer (500) constructed in accordance with the hierarchical anchoring architecture. The MEMS transducer (500) comprises a substrate (501), a middle membrane layer (503), a top membrane layer (505), and a bottom membrane layer (507). A base dielectric layer (510) is disposed on a surface of the substrate (501). In some embodiments, the substrate (501) comprises any of silicon, glass, ceramic, polymer, silicon-on-insulator (SOI), or combinations thereof. In some embodiments, the base dielectric layer (510) comprises a material characterized by resistance to hydrofluoric acid (HF) and vapor-phase hydrofluoric acid (VHF) etching. Examples of materials for the base dielectric layer (510) include but are not limited to SiN, SiRN, TiN, TaO, TaN, AlOx, and combinations thereof.

In the hierarchical anchoring architecture, the middle membrane layer (503) constitutes the sole structural interface between the MEMS transducer (500) and the substrate (501). The middle membrane layer (503) is anchored to the substrate (501) via at least two primary support posts (509). The primary support posts (509) extend from the middle membrane layer (503) through one or more sacrificial or dielectric layers to the base dielectric layer (510) and the substrate (501). In some embodiments, one or more of layers (503, 505, 507) are electrically connected to one or more bond pads (520). Bond pads (520) include at least a conductive portion amenable to wire bonding, wedge bonding, bumping, or other electrical connection from the MEMS transducer (500) to an external package. A conductive trace or interconnect (522) provides electrical routing between the bond pad (520) and one or more of the membrane layers (503, 505, 507). Examples of external package include but are not limited to PCB substrates or laminates, metal can, polymer, glass, Liquid Crystal Polymer, or other metal, polymer, ceramic, or glass substrates and/or lids. A bond pad (520) is in mechanical contact with the substrate (501) through one or more bond pad pillars (524). In a further example, the bond pad (520) top view area is smaller than the bond pad pillar (524) top view area to ensure mechanical support of the bond pad. In a further example, the primary support posts (509) comprise a conductive core surrounded by or encapsulated within at least one dielectric material resistant to HF or VHF etching. Examples of conductive materials for the primary support posts (509) include but are not limited to doped polysilicon, Al, AlCu, AlSiCu, Ni, and combinations thereof. Examples of dielectric materials for the primary support posts (509) include but are not limited to SiN, TiN, TaO, and combinations thereof.

The top membrane layer (505) and the bottom membrane layer (507) are each in mechanical communication with the middle membrane layer (503) via at least one membrane support post (511, 513). Either the top membrane layer (505) or the bottom membrane layer (507) is used in the description below to illustrate the structural principle. The middle membrane layer (503) includes one or more conductive portions (527) and non-conductive portions (525). In a further example, conductive portions (527) are positioned below or above at least a portion of the membrane layers (505, 507) to provide a reference voltage to the membrane layer structures (505, 507) and to generate an electrostatic force on the membrane layer structures (505, 507), causing them to move in the direction of the middle membrane layer (503). In a further example, the non-conductive portions (525) are located at the location of the support post (511, 513) contact area with the middle membrane layer (503) and extend beyond the contact area. In a further example, an additional dielectric structure (512, 514) is defined above (512) and below (514) the non-conductive portions (525). In a further example, the additional dielectric structures (512, 514) extend beyond the non-conductive portions (525) so that the additional dielectric structures are in communication with both the non-conductive portions (525) and the conductive portions (527). Optional anti-stiction structures (516, 518) may be disposed below (516) and above (518) the middle membrane layer (503) to prevent contact adhesion between the membrane layers and the middle membrane layer. Examples of materials for the conductive portions include but are not limited to doped polysilicon, metals, Al, Zinc, Copper, graphene, or CNT. Examples of materials for the non-conductive portions (525) include but are not limited to SiO2, TEOS, amorphous Silicon, SiN, SiRN, TaO, TaN, TiN, AlN, or AlScN. In a further example, the non-conductive portions (525) may be damaged or etched during the sacrificial material etch used to release the membrane structures. To prevent damage to the non-conductive portions (525), the additional dielectric structures (512, 514) extend over the non-conductive portions (525) and prevent access of the etching material to the non-conductive portions. Examples of materials for the additional dielectric structures (512, 514) include but are not limited to SiN, SiRN, TiN, TaO, TaN, or other non-conductive dielectric materials.

One non-limiting example of a method for manufacturing the structure of FIG. 5 includes the following process steps: depositing a base dielectric layer (510) on a silicon substrate or wafer (501); optionally patterning the base dielectric layer (510) to define dicing lanes or other structures on the wafer; depositing a first sacrificial layer on the base dielectric layer (510); patterning the first sacrificial layer to define at least the middle membrane support post (509) and pad support structures (524); depositing a bottom membrane layer (507) which extends into the support post (509) openings to form support posts after layer definition and sacrificial material removal; optionally applying a CMP step to obtain a flat surface; patterning the bottom membrane layer to define membrane structures (507); depositing a second sacrificial layer; patterning the second sacrificial layer to define at least the support posts (511, 513); depositing a support post layer extending into the patterned second sacrificial layer; applying a CMP step; depositing an additional dielectric layer (forming layer 514); patterning the additional dielectric layer to provide bottom membrane support post (511, 513) landing structures (514) and optional anti-stiction prevention structures (516); depositing a middle membrane layer (503); patterning the middle membrane layer (503) to define non-conductive portions (525); depositing a third sacrificial layer; applying a CMP step; depositing a second additional dielectric layer (to define 512); patterning the second additional dielectric layer to define top membrane post landing structures (512) and optional anti-stiction prevention structures (518); the top membrane post landing structure (512) isolates the non-conductive portions (525) from the sacrificial layer etch and maintains their integrity; depositing and patterning a fourth sacrificial layer for the support posts (511, 513); depositing a top membrane layer (505) with material extending into the sacrificial layer to define the posts (511, 513); patterning the top membrane layer (505); depositing and patterning bond pads; etching the wafer (501) from the backside to create a backside hole (540); and removing the sacrificial layers with HF and/or VHF.

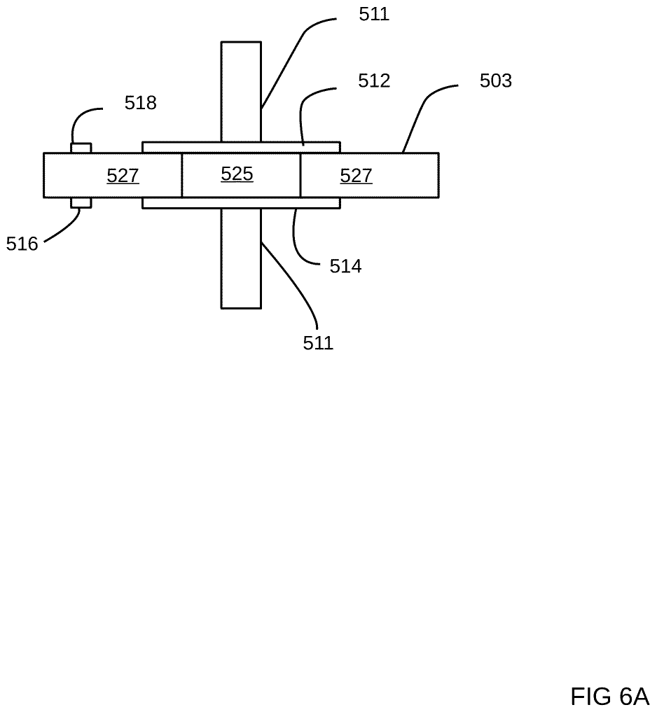

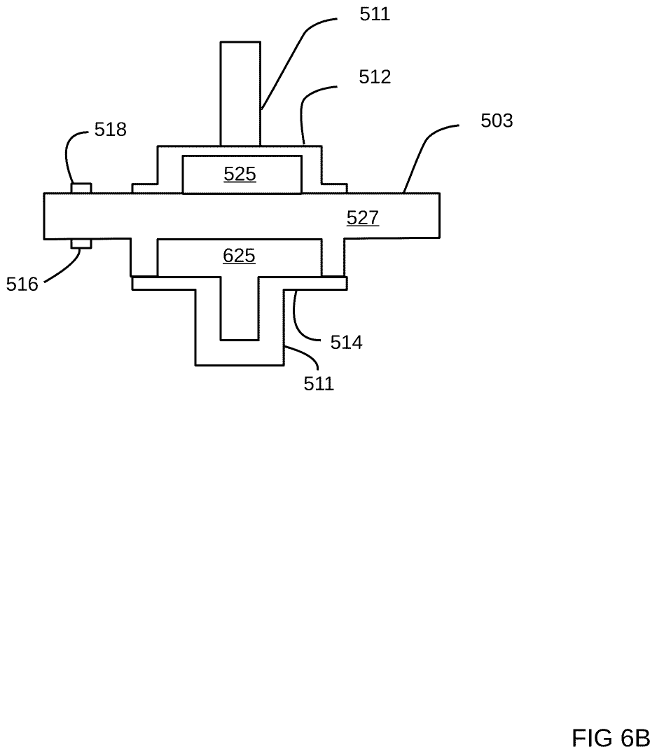

FIG. 6A is an example of a detailed cross-sectional view of an isolation island as described in FIG. 5. The isolation island comprises the non-conductive portion (525) of the middle membrane layer (503), the additional dielectric structures (512, 514) above and below the non-conductive portion (525), the membrane support posts (511) extending through the additional dielectric structures, and optional anti-stiction structures (516, 518). The additional dielectric structures (512, 514) extend laterally beyond the non-conductive portion (525) and overlap with the conductive portions (527), thereby sealing the non-conductive portion from the sacrificial etch.

FIG. 6B is an alternative example of a detailed cross-sectional view of an isolation island, illustrating an alternative process flow for the middle membrane layer. This method enables creation of the isolation island without a CMP step. The method follows the steps described above up to the deposition and etching of the second sacrificial layer for the support posts (511, 513); an additional dielectric layer (514) is deposited and patterned to define post support and optional anti-stiction structures. A third sacrificial layer is deposited including in the post location isolation area (625); the third sacrificial layer is patterned to create the isolation area (625); the middle membrane layer (503) is deposited and patterned to create the middle membrane; protection of the isolation area (625) from the sacrificial etch is obtained because on one side the additional dielectric area (514) encompasses the isolation area (625) and on the other side the middle membrane layer (503) encompasses the isolation structure (625), preventing any etchant from reaching the isolation area (625); a fourth sacrificial layer is deposited and patterned to create the isolation island (525); an additional dielectric area is deposited and patterned to cover the isolation island (525) and define optional anti-stiction structures (518).

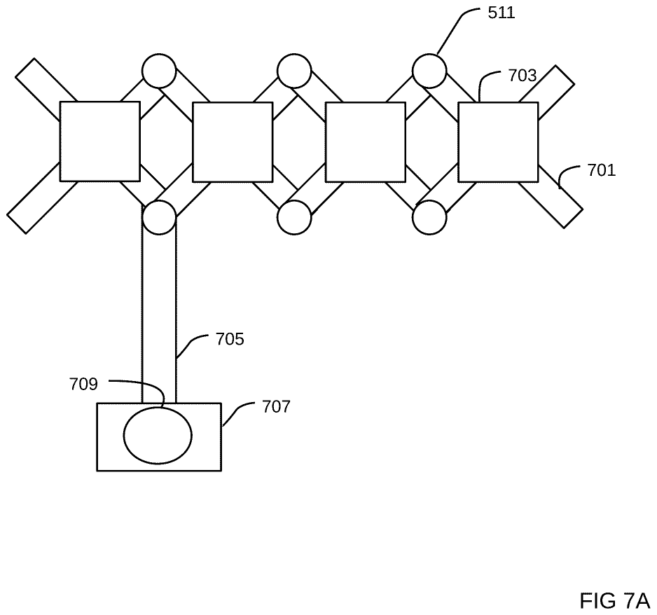

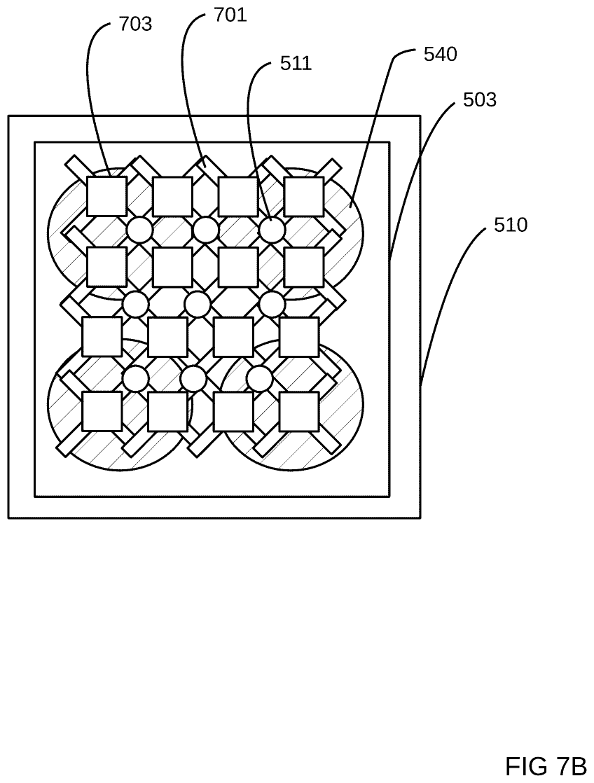

FIG. 7A is an example of a top view of a membrane (701), spoke (703), and post (511). The spoke (703) and membrane (701) are defined in the same layer and are represented as two items to highlight their respective functions, where the spoke (703) provides mechanical support and enables movement of the membrane (701). Support posts (511) are configured at the edges of the spokes (703). In a further example, a pad (709) is configured on a top pad support (707). The spokes (703) provide electrical connection between membranes (701). A pad connection (705) is configured in the membrane layer and provides electrical connection between the spokes (703), membranes (701), and pads (709).

FIG. 7B is an example of a top view of the speaker device using the hierarchical anchoring architecture. The base dielectric layer (510) extends over the device area and is larger than the middle membrane layer (503). The middle membrane layer (503) is in continuous contact with the base dielectric layer (510) at the edge of the middle membrane layer. In an alternative example, the middle membrane layer (503) is in contact with at least 70%; 80%; 90%; 95%; or 99% of its periphery with the base dielectric layer (510). A backside etch hole (540) is located under one or more membranes (701), spokes (703), and support posts (511). There is little distinction left between hardware and software implementations of aspects of systems; the use of hardware or software is generally (but not always, in that in certain contexts the choice between hardware and software can become significant) a design choice representing cost versus efficiency tradeoffs. There are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Versatile Disk (DVD), a digital tape, a computer memory, etc.; and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to disclosures containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”. Speaker and picospeaker are interchangeable and can be used in place of the other.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A MEMS transducer comprising:
a substrate;
a base dielectric layer disposed on a surface of the substrate;
a middle membrane layer anchored to the substrate via at least two primary support posts extending through at least one dielectric layer to the base dielectric layer, the middle membrane layer constituting the sole structural interface for supporting membrane layers between the MEMS transducer and the substrate; and
at least one of a top membrane layer and a bottom membrane layer mechanically suspended from the middle membrane layer via at least one membrane support post;
wherein the middle membrane layer comprises one or more conductive portions and one or more non-conductive portions, the non-conductive portions positioned at contact areas of the membrane support posts with the middle membrane layer.

2. The MEMS transducer of claim 1, further comprising additional dielectric structures disposed above and below the non-conductive portions, the additional dielectric structures extending beyond the non-conductive portions and overlapping with the conductive portions to protect the non-conductive portions from a sacrificial layer etch.

3. The MEMS transducer of claim 1, wherein the primary support posts comprise a conductive core surrounded by or encapsulated within at least one dielectric material resistant to hydrofluoric acid or vapor-phase hydrofluoric acid etching.

4. The MEMS transducer of claim 1, further comprising at least one bond pad electrically connected to one or more of the middle membrane layer, the top membrane layer, and the bottom membrane layer, the bond pad in mechanical contact with the substrate through at least one bond pad pillar, and a conductive trace providing electrical routing between the bond pad and one or more of the membrane layers.

5. The MEMS transducer of claim 1, further comprising anti-stiction structures disposed between the middle membrane layer and at least one of the top membrane layer and the bottom membrane layer.

6. A method of manufacturing a MEMS transducer having a hierarchical anchoring architecture, the method comprising the steps of:
depositing a base dielectric layer on a substrate;
depositing and patterning a first sacrificial layer to define primary support post locations;
depositing a bottom membrane layer extending into the primary support post locations;
patterning the bottom membrane layer to define membrane structures;
depositing and patterning a second sacrificial layer to define membrane support post locations;
depositing a first additional dielectric layer and patterning to form support post landing structures;
depositing a middle membrane layer and patterning to define non-conductive isolation portions at support post contact areas;
depositing a second additional dielectric layer and patterning to form top membrane post landing structures that protect the non-conductive isolation portions from a subsequent sacrificial etch;
depositing a top membrane layer extending into the membrane support post locations and patterning the top membrane layer;
etching the substrate from a backside to create a backside hole; and
removing sacrificial layers to release the membrane structures, wherein the middle membrane layer constitutes the sole structural interface for supporting membrane layers between the MEMS transducer and the substrate,
wherein the top membrane layer and the bottom membrane layer are mechanically suspended from the middle membrane layer.

7. The method of claim 6, wherein removing the sacrificial layers comprises etching with HF, VHF, or a combination thereof, and wherein the base dielectric layer comprises a material resistant to HF and VHF etching selected from the group consisting of SiN, SiRN, TiN, TaO, TaN, AlOx, and combinations thereof.

8. The method of claim 6, further comprising applying a chemical-mechanical planarization step after depositing the bottom membrane layer to obtain a flat surface.

9. The method of claim 6, wherein defining the non-conductive isolation portions comprises disposing a non-conductive material within the middle membrane layer at the support post contact areas, the non-conductive material being protected from the subsequent sacrificial etch by the first and second additional dielectric layers extending over the non-conductive material.

10. The method of claim 6, further comprising depositing and patterning bond pads electrically connected to at least one of the middle membrane layer, the top membrane layer, and the bottom membrane layer prior to etching the substrate from the backside.

11. The method of claim 6, wherein depositing the middle membrane layer and patterning to define non-conductive isolation portions comprises: depositing a third sacrificial layer in a post location to form an isolation area; patterning the third sacrificial layer to define the isolation area; depositing the middle membrane layer over the isolation area such that the middle membrane layer encompasses the isolation area on one side and the first additional dielectric layer encompasses the isolation area on an opposite side, thereby protecting the isolation area from the subsequent sacrificial etch without requiring a chemical-mechanical planarization step.

12. A speaker device comprising:
a substrate having a backside etch hole;
a base dielectric layer disposed on the substrate, the base dielectric layer extending over a device area;
a middle membrane layer anchored to the substrate via primary support posts, the middle membrane layer comprising a plurality of membrane structures connected by spokes, the spokes providing mechanical support and electrical interconnection between the membrane structures, and membrane support posts configured at edges of the spokes; and
at least one of a top membrane layer and a bottom membrane layer mechanically suspended from the middle membrane layer via the membrane support posts; and
wherein the middle membrane layer is in continuous contact with the base dielectric layer along at least 70% of its periphery, and the base dielectric layer is larger than the middle membrane layer.

13. The speaker device of claim 12, further comprising at least one bond pad configured on a pad support, and a pad connection configured in the membrane layer providing electrical connection between the spokes, the membrane structures, and the bond pad.

14. The speaker device of claim 12, wherein the middle membrane layer further comprises conductive portions positioned below or above at least a portion of the top or bottom membrane layers to provide a reference voltage and generate an electrostatic force on the membrane layers.

15. The speaker device of claim 12, wherein the middle membrane layer further comprises non-conductive portions at locations of the membrane support post contact areas with the middle membrane layer, and additional dielectric structures disposed above and below the non-conductive portions to protect the non-conductive portions from a sacrificial etch.

16. The speaker device of claim 12, wherein the substrate comprises any of silicon, glass, ceramic, polymer, silicon-on-insulator, or combinations thereof, and wherein the base dielectric layer comprises a material characterized by resistance to hydrofluoric acid and vapor-phase hydrofluoric acid etching.

17. The speaker device of claim 12, wherein the spokes define a mechanical resonance frequency of the membrane structures, and wherein the membrane support posts are positioned at junctions between adjacent spokes.
